(19) United States
(12) Patent Application Publication
(10) Pub. No.: US 2026/0333869 A1
(43) Pub. Date: Oct. 22, 2026

(54) DISPLAY PANEL, METHOD FOR MANUFACTURING SAME, AND DISPLAY DEVICE

(71) Applicant: Guangzhou China Star Optoelectronics Semiconductor Display Technology Co., LTd., Guangzhou (CN)

(72) Inventors: Weiran CAO, Guangzhou (CN); Yuanjun HSU, Guangzhou (CN); Shan LI, Guangzhou (CN); Bin ZHAO, Guangzhou (CN); Zhirong SU, Guangzhou (CN); Daoping YU, Guangzhou (CN); Zhongjie LIU, Guangzhou (CN)

(73) Assignee: Guangzhou China Star Optoelectronics Semiconductor Display Technology Co., LTd., Guangzhou (CN)

(21) Appl. No.: 19/253,950

(22) Filed: Jun. 29, 2025

(30) Foreign Application Priority Data
Apr. 21, 2025 (CN) 202510507821.2

(51) Int. Cl. H10D 86/40; H10D 86/01

(52) U.S. Cl. CPC H10D 86/441; H10D 86/0221

(57) ABSTRACT

A display panel, a method for manufacturing the display panel, and a display device are provided. The display panel includes a substrate, an active layer, and a conductive layer. The conductive layer and the active layer are simultaneously patterned, ensuring that the side surface of the patterned conductive layer is continuous with the side surface of the active layer. An edge of the conductive layer is retracted inward compared to an edge of a same side of the active layer by a width greater than or equal to 1 micron and less than or equal to 1.3 microns.

### CROSS-REFERENCE TO RELATED APPLICATIONS

This application claims priority to and the benefit of Chinese Patent Application No. 202510507821.2, filed on Apr. 21, 2025, which is incorporated herein by reference in its entirety.

### TECHNICAL FIELD

The present disclosure relates to the field of display technologies, and in particular, to a display panel, a method for manufacturing a display panel, and a display device.

### BACKGROUND

The remarkable advantages of large size, high frame rate processing and high transmittance in visible light range have broad application prospects in the fields of active-matrix liquid crystal display and active-matrix organic electroluminescent diode. The increase of the size of the display panel may lead to reducing the capacitor-resistance delay effect of metal traces. Metallic copper is widely used because of its low resistance and low cost, but copper ions are easy to diffuse into the active layer during the subsequent high temperature manufacturing process, creating defects, and degrading the electrical performance of devices. In order to block the influence of copper ion diffusion on device performance, molybdenum, titanium, or molybdenum-titanium alloy are widely used as barrier layer materials in the industry to avoid the influence of copper ion diffusion.

However, in the actual manufacturing process, due to the relatively slow etching rate of molybdenum, titanium or molybdenum-titanium alloy by the etching solution, the etching time is relatively long and critical dimension loss (CD Loss) is larger, resulting in a large missing critical dimension of the metal layer, which cannot meet the refined requirements of the display panel for the manufacturing process.

### SUMMARY

In a first aspect, the present disclosure provides a display panel, including:
a substrate;
an active layer disposed on a side of the substrate;
a conductive layer disposed on a side of the active layer away from the substrate;
where an edge of the conductive layer is retracted inward compared to an edge of a same side of the active layer by a width greater than or equal to 1 micron and less than or equal to 1.3 microns.

In a second aspect, the present disclosure provides a method for manufacturing a display panel, the method for manufacturing the display panel including:
forming a semiconductor material layer on a side of the substrate;
forming a conductive material layer on a side of the semiconductor material layer away from the substrate;
forming a photoresist layer on the conductive material layer;
exposing and developing the photoresist layer using a photomask to form a first photoresist pattern;
simultaneously performing a first etching on the conductive material layer and the semiconductor material layer using the first photoresist pattern to form a conductive portion and an active layer, where a side surface of the conductive portion is continuous with a side surface of the active layer;
thinning the first photoresist pattern using the photomask to form a second photoresist pattern; and
performing a second etching on the conductive portion using the second photoresist pattern to form a conductive layer;
where an edge of the conductive layer is retracted inward compared to an edge of a same side of the active layer by a width greater than or equal to 1 micron and less than or equal to 1.3 microns.

In a third aspect, the present disclosure further provides a display device including the display panel as described above.

### BRIEF DESCRIPTION OF THE DRAWINGS

In order to describe the embodiments of the present disclosure clearly, the following will briefly illustrate the drawings involved in the description of the present disclosure. Obviously, the drawings described below are only some embodiments of the present disclosure, for those skilled in the art, without the premise of creative labor, may also obtain other drawings according to these drawings.

For a more complete understanding of the present disclosure and its beneficial effects, the following description will be made in combination with the drawings, and the same reference numerals refer to the same parts in the following description.

FIG. 1 is a top view of a display panel according to some embodiments of the present disclosure.

FIG. 2 is a cross-sectional view of a display panel according to some embodiments of the present disclosure along the A-A′ direction shown in FIG. 1.

FIG. 3 is a cross-sectional view of the display panel according to some embodiments of the present disclosure along the B-B′ direction shown in FIG. 1.

FIG. 4 is another schematic structural view of the display panel according to some embodiments of the present disclosure.

FIG. 5 is a flowchart of a method for manufacturing the display panel according to some embodiments of the present disclosure.

FIGS. 6A to 6E are flow diagrams of a method for manufacturing the display panel according to some embodiments of the present disclosure.

FIG. 7 is a schematic diagram of the display device according to some embodiments of the present disclosure.

### DETAILED DESCRIPTION

With reference to the drawings provided in the embodiments of the present disclosure, a clear and comprehensive description of the technical solutions in these embodiments is provided in the following. Obviously, the described embodiments are only a part of embodiments of the present disclosure, and not all of the embodiments. Based on the embodiments in the present disclosure, all other embodiments obtained by those skilled in the art without making creative efforts fall within the scope of protection of the present disclosure.

The embodiments of the present disclosure provide a display panel. The display panel includes a substrate, an active layer, and a conductive layer. The active layer is disposed on a side of the substrate, the conductive layer is disposed on a side of the active layer away from the substrate. The conductive layer is disposed retracted inward compared to an edge of a same side of the active layer by a width greater than or equal to 1 micron and less than or equal to 1.3 microns.

In the embodiments of the present disclosure, by simultaneously patterning the conductive layer and the active layer, the side surface of the patterned conductive layer is continuous with the side surface of the active layer. So that, it may be avoided that the etching solution undercuts the conductive layer from the bottom of the active layer during the second patterning process, so that the conductive layer may be retracted inward compared to an edge of a same side of the active layer by a width greater than or equal to 1 micron and less than or equal to 1.3 microns, thereby improving the situation of CD loss.

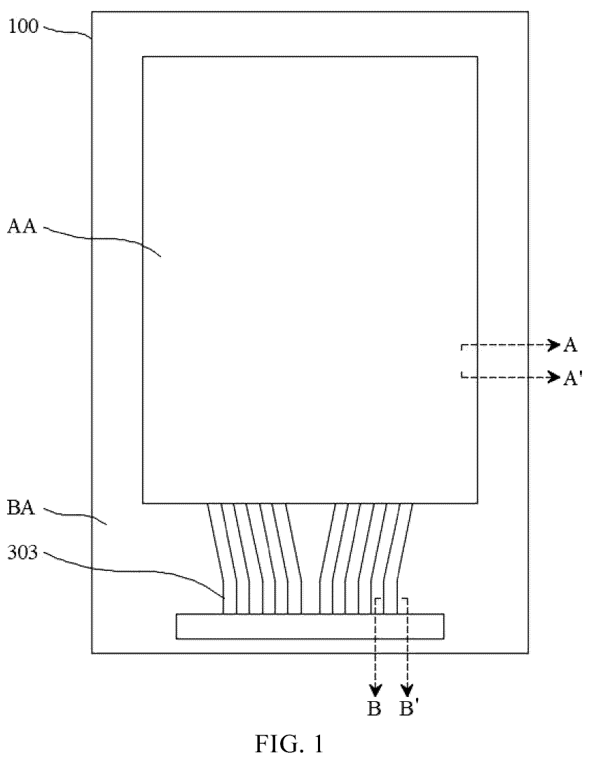

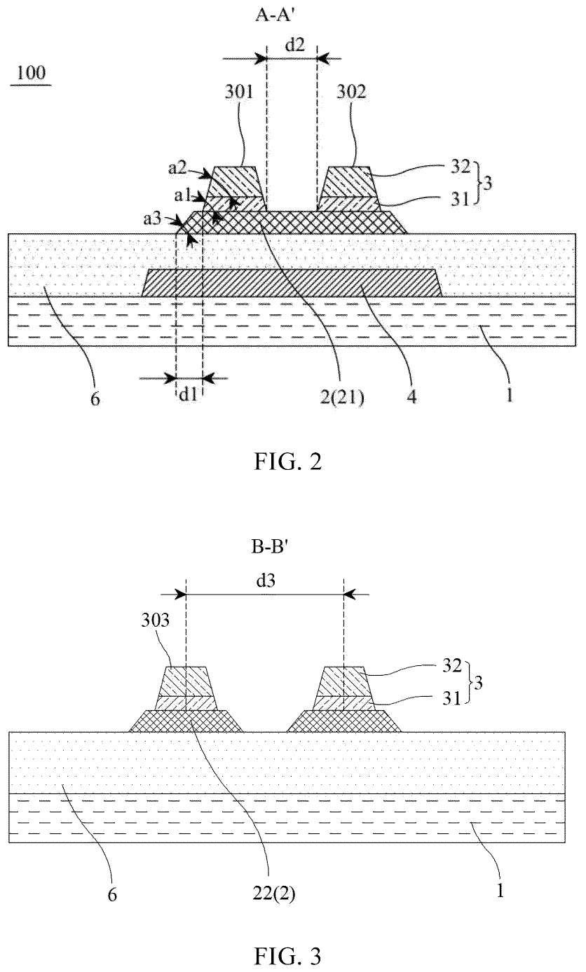

Referring to FIGS. 1 and 2, FIG. 1 is a top view of a display panel according to some embodiments of the present disclosure of the present disclosure. FIG. 2 is a cross-sectional view of a display panel according to some embodiments of the present disclosure along the A-A′ direction shown in FIG. 1. The display panel includes a display area AA and a border area BA provided at the periphery of the display area AA, and the display panel 100 includes a substrate 1, an active layer 2 provided on a side of the substrate 1, and a conductive layer 3 provided on a side of the active layer 2 away from the substrate 1.

Referring to FIG. 2, the conductive layer 3 is a double-layer conductive structure, and the conductive layer 3 includes a first sub-conductive layer 31 and a second sub-conductive layer 32. The first sub-conductive layer 31 is disposed on the surface of the active layer 2 away from the substrate 1. The second sub-conductive layer 32 is disposed on the surface of the first sub-conductive layer 31 away from the active layer 2.

The edge of the conductive layer 3 is disposed retracted inward from the edge of a same side of the active layer 2, and the retraction width d1 of the edge of the conductive layer 3 with respect to the edge of a same side of the active layer 2 is greater than or equal to 1 micron and less than or equal to 1.3 micron, as shown in FIG. 2.

In some embodiments, the active layer 2 and the conductive layer 3 are simultaneously subjected to a first patterning process, and then the conductive layer 3 is separately subjected to a second patterning process. After the active layer 2 and the conductive layer 3 are simultaneously subjected to the first patterning process, the side surface of the active layer 2 is continuous with the side surface of the conductive layer 3, so that the etching solution can avoid undercutting the conductive layer 3 from the bottom of the active layer 2 during the second patterning process, and thus can improve the situation that the critical dimension is missing. So that, the retraction width of the edge of the conductive layer 3 is reduced from 1.4 to 1.7 microns to 1 to 1.3 microns compared with the edge of a same side of the active layer 2, and the process accuracy of the display panel can be improved.

In some embodiments, the ratio of the thickness of the first sub-conductive layer 31 to the thickness of the second sub-conductive layer 32 is greater than or equal to 0.015 and less than or equal to 0.072.

It should be noted that, since the etching selectivity ratio of the material of the first sub-conductive layer 31 is smaller than the etching selectivity ratio of the material of the second sub-conductive layer 32, if the ratio of the thickness of the first sub-conductive layer 31 to the thickness of the second sub-conductive layer 32 is too small, it means that the thickness of the first sub-conductive layer 31 is thinner, the first sub-conductive layer 31 cannot provide good adhesion to the second sub-conductive layer 32, the problem of film peeling is likely to occur to the second sub-conductive layer 32, and there will also be the problem of poor effect in blocking copper diffusion. If the ratio of the thickness of the first sub-conductive layer 31 to the thickness of the second sub-conductive layer 32 is too large, it means that the thickness of the first sub-conductive layer 31 is too large, and this will make the etching time of the first sub-conductive layer 31 longer, resulting in less improvement in CD loss.

In some embodiments, by reducing the thickness of the first sub-conductive layer 31 of the conductive layer 3 so that the ratio of the thickness of the first sub-conductive layer 31 to the thickness of the second sub-conductive layer 32 is greater than or equal to 0.015 and less than or equal to 0.072, the etching time of the first sub-conductive layer 31 may be reduced, and thus critical dimension loss of the active layer 2 and the conductive layer 3 can be improved.

In some embodiments, the material of the first sub-conductive layer 31 includes any one of molybdenum, a molybdenum-titanium alloy, and a molybdenum-niobium alloy, and the material of the second sub-conductive layer 32 includes copper.

In some embodiments, referring to FIG. 1, the thickness of the first sub-conductive layer 31 is greater than or equal to 120 microns and less than or equal to 180 microns, and the thickness of the second sub-conductive layer 32 is greater than or equal to 2500 microns and less than or equal to 8000 microns. For example, the thickness of the first sub-conductive layer 31 may be 120 microns, 140 microns, 160 microns, 180 microns, etc., and the thickness of the second sub-conductive layer 32 may be 2500 microns, 3000 microns, 5000 microns, 7000 microns, or 8000 microns, etc.

It should be noted that the etching selectivity ratio of the material of the first sub-conductive layer 31 is smaller than the etching selectivity ratio of the material of the second sub-conductive layer 32. If the thickness of the first sub-conductive layer 31 is too large, the etching time of the first sub-conductive layer 31 becomes longer, and the degree of improvement of the CD loss is smaller. If the thickness of the first sub-conductive layer 31 is too small, the first sub-conductive layer 31 cannot provide good adhesion for the second sub-conductive layer 32, the second sub-conductive layer 32 is likely to have a problem of film peeling, and the effect of blocking copper diffusion is not good. By limiting the thickness of the first sub-conductive layer 31 to a range of 120 microns to 180 microns, and limiting the thickness of the second sub-conductive layer 32 to a range from 2500 microns to 8000 microns, not only may the problem of film peeling of the second sub-conductive layer 32 be prevented, and the copper in the second sub-conductive layer 32 may be blocked from diffusing to the active layer 2, but also CD loss of the active layer 2 and the conductive layer 3 may be improved.

In some embodiments, the side surface of the first sub-conductive layer 31 is disposed continuously with the side surface of the second sub-conductive layer 32.

Referring to FIG. 2, taking the plane on which the first sub-conductive layer 31 is located as a horizontal plane, the side surface of the first sub-conductive layer 31 is inclined with respect to the bottom surface of the first sub-conductive layer 31, and the side surface of the second sub-conductive layer 32 is inclined with respect to the bottom surface of the second sub-conductive layer 32. That the side surface of the first sub-conductive layer 31 is disposed continuously with the side surface of the second sub-conductive layer 32 means that the side surface of the first sub-conductive layer 31 and the side surface of the second sub-conductive layer 32 are connected to each other and are in the same inclined surface. In this way, it is possible to avoid forming a step at the joint of the side surfaces of the first sub-conductive layer 31 and the second sub-conductive layer 32, improve the flatness of the film layer subsequently deposited on the conductive layer 3, and it is possible to avoid display abnormality caused by the occurrence of a situation in which the film layer subsequently deposited generates cracks at the side surfaces of the first sub-conductive layer 31 and the second sub-conductive layer 32.

In some embodiments, referring to FIG. 2, a first included angle a1 is positioned between the side surface of the first sub-conductive layer 31 and the bottom surface of the first sub-conductive layer 31, a second included angle a2 is positioned between the side surface of the second sub-conductive layer 32 and the bottom surface of the second sub-conductive layer 32. In some embodiments, the first included angle a1 and the second included angle a2 are the same.

In some embodiments, the first included angle a1 is greater than or equal to 40 degrees and less than or equal to 70 degrees. For example, the first included angle a 1 is 40 degrees, 45 degrees, 50 degrees, 55 degrees, 60 degrees, 65 degrees, 70 degrees, or the like.

In some embodiments, referring to FIG. 2, a third included angle a3 is positioned between the side surface of the active layer 2 and the bottom surface of the active layer 2. The third included angle a3 is smaller than the first included angle a1.

It should be noted that the conductive layer 3 needs to be etched twice, and the first etching to the conductive layer 3 is a patterning process simultaneously with the active layer 2. When the conductive layer 3 is etched for the second time, the etching solution etches the conductive layer 3 again, and the degree of etching the conductive layer 3 increases, and the included angle between the side surface of the conductive layer 3 and the bottom surface of the conductive layer 3 also increases accordingly.

In some embodiments, referring to FIG. 2, the third included angle a3 is greater than or equal to 30 degrees and less than or equal to 50 degrees. For example, the third included angle a3 may be 30 degrees, 35 degrees, 40 degrees, 45 degrees, 50 degrees, or the like. In this way, the active layer 2 may have a smaller slope angle. A smaller slope angle requires lower process accuracy of the display panel, so that a high process yield of the active layer 2 can be ensured.

In some embodiments, referring to FIG. 2, the orthographic projection of the conductive layer 3 on the active layer 2 is located within the active layer 2.

It should be noted that in the actual manufacturing process, the active layer 2 is patterned together with the conductive layer 3 after the conductive layer 3 is formed. By patterning the conductive layer 3 and the active layer 2 with the same photomask, one photomask may be saved. After the etching to the active layer 2 is completed, the conductive layer 3 needs to be subjected to a second patterning process. The area of the conductive layer 3 is smaller than the area of the active layer 2, and the orthographic projection of the conductive layer 3 on the active layer 2 is located within the active layer 2.

In some embodiments, referring to FIG. 2, the conductive layer 3 includes a plurality of patterned sources 301 and drains 302, both of which are double-layer conductive structures formed by stacking a first sub-conductive layer 31 and a second sub-conductive layer 32. The active layer 2 includes a plurality of patterned first active portions 21, and the sources 301 and the drains 302 are spaced apart and disposed on the surface of the first active portion 21 away from the substrate 1.

Referring to FIG. 2, the first active portion 21, the source 301, and the drain 302 are a part of a transistor. The first active portion 21 includes a channel portion located between the source 301 and the drain 302. The distance d2 between the source 301 and the drain 302 is greater than or equal to 3 microns and less than or equal to 3.5 microns along the channel length direction of the first active portion 21. The distance d2 between the source 301 and the drain 302 is the channel length of the channel portion of the first active portion 21.

In some embodiments, a first patterning process is performed simultaneously to the conductive layer 3 and the active layer 2, so that the side surface of the conductive layer 3 after the first patterning process is continuous with the side surface of the active portion, and it may be avoided that the etching solution undercuts the conductive layer from the bottom of the active layer during the second patterning process, so that CD loss may be improved. The widths of the source 301 and the drain 302 may be increased, thereby reducing the distance d2 between the source 301 and the drain 302. In this way, the channel length of the transistor may be reduced, thereby increasing the mobility, the switching speed, and current driving capability of the transistor.

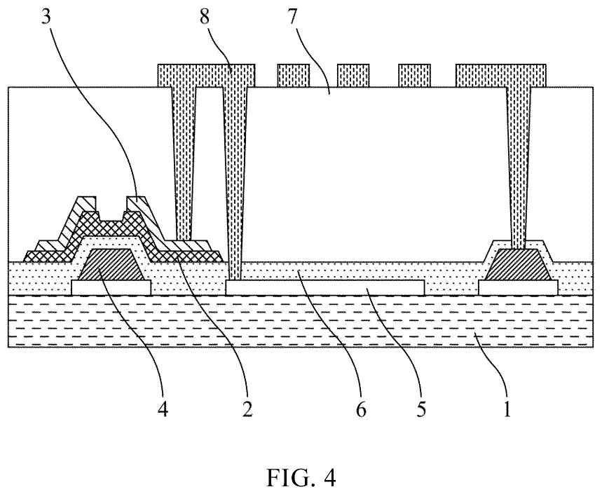

FIG. 3 is a cross-sectional view of the display panel according to some embodiments of the present disclosure along the B-B′ direction shown in FIG. 1. The conductive layer 3 includes a plurality of fan-out traces 303, the fan-out traces 303 are provided in the border area BA, and the fan-out traces 303 are connected between the bonding area and the display area AA. The active layer 2 includes a plurality of second active portions 22, and the orthographic projections of the fan-out traces 303 on the active layer 2 are located in the second active portions 22.

In some embodiments, referring to FIGS. 1 and 3, the distance d3 between centers of two adjacent fan-out trace 303 is greater than or equal to 7 microns and less than or equal to 8 microns along a line width direction of the fan-out traces. For example, the distance d3 between centers of two adjacent fan-out trace 303 is 7 microns, 7.2 microns, 7.4 microns, 7.6 microns, 7.8 microns, 8 microns, etc.

In other embodiments, a first patterning process is performed simultaneously to the conductive layer 3 and the active layer 2, so that the side surface of the conductive layer 3 after the first patterning process is continuous with the side surface of the active portion, and it may be avoided that the etching solution undercuts the conductive layer from the bottom of the active layer 2 during the second patterning process, so that the CD loss may be improved. The distance between centers of any two adjacent fanout traces 303 in the border area BA may be reduced, so as to reduce the space occupied by the fan-out traces 303. The width of the border area of the display panel may be increased.

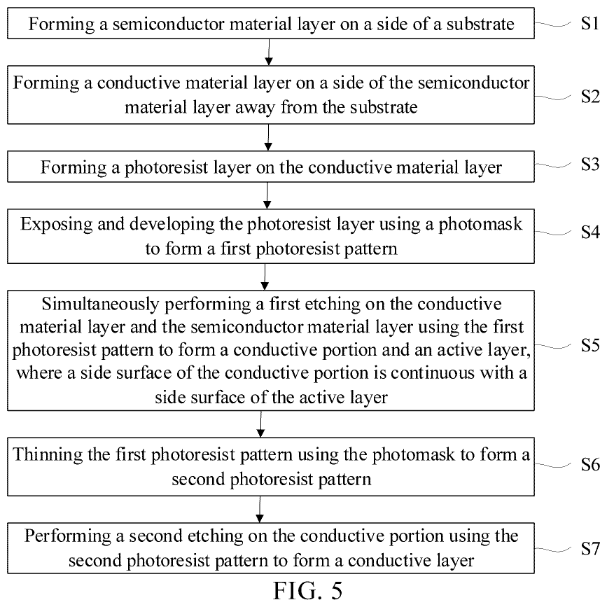

FIG. 4 is another schematic structural view of a display panel 100 according to some embodiments of the present disclosure. The display panel 100 includes a gate 4, and the gate 4 is disposed between the active layer 2 and the substrate 1.

Referring to FIG. 4, the transistor has a back channel etching structure, the gate 4 is provided on the side of the active layer 2 close to the substrate 1, and the conductive layer 3 is provided on the surface of the active layer 2 away from the gate 4, and the conductive layer 3 is a source and drain layer.

In some embodiments, referring to FIG. 4, the display panel 100 is a liquid crystal display panel. The display panel 100 includes a first electrode layer 5, a gate 4, a gate insulating layer 6, an active layer 2, a conductive layer 3, a passivation layer 7, and a second electrode layer 8 which are sequentially stacked on the substrate 1.

It should be noted that FIG. 4 schematically illustrates the relative positional relationship between the gate 4, the active layer 2, and the conductive layer 3 in the display panel 100, and does not represent the structure of the display panel 100 in practical applications. In practical applications, the display panel may be replaced with the structure of other liquid crystal display panels to achieve the same or similar functions.

In practical applications, the type of the display panel is not limited to the liquid crystal display panel in the above-described embodiments, and the display panel may be an organic light-emitting diode display panel, a mini light-emitting diode display panel, or a micro light-emitting diode display panel.

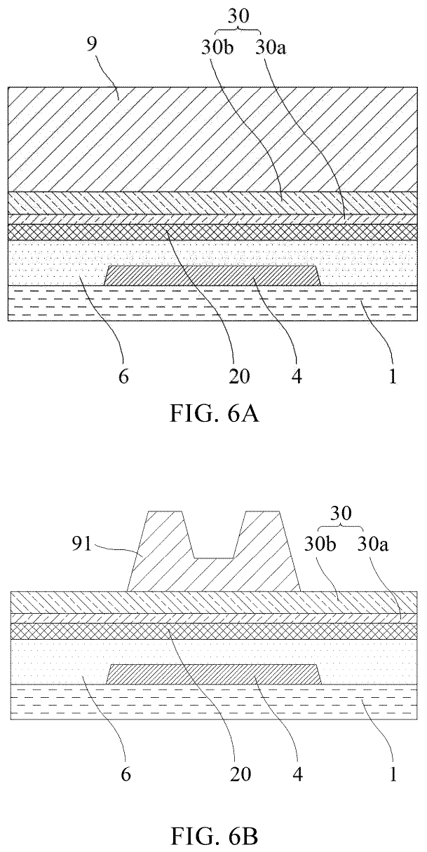

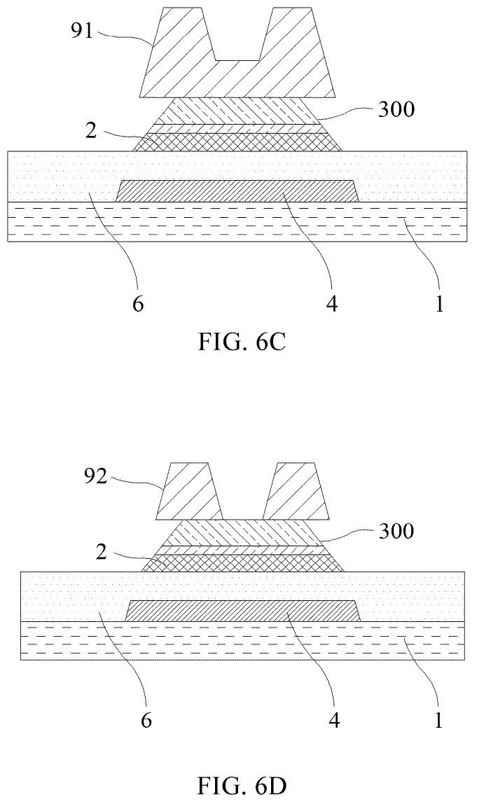

Based on the display panel 100 provided by the above embodiments of the present disclosure, the embodiments of the present disclosure further provide a method of manufacturing the display panel. Referring to FIGS. 5 and 6A to 6E, FIG. 5 is a flowchart of a method for manufacturing the display panel provided by embodiments of the present disclosure, and FIGS. 6A to 6E are flow diagrams of a method for manufacturing the display panel according to some embodiments of the present disclosure. The method for manufacturing the display panel includes the following steps S1 to S7.

At step S1, a semiconductor material layer 20 is formed on a side of the substrate 1.

At step S2, a conductive material layer 30 is formed on a side of the semiconductor material layer 20 away from the substrate 1.

At step S3, Forming the photoresist layer 9 on the conductive material layer 30.

At step S4, exposure and development processing is performed on the photoresist layer 9 using a photomask to form a first photoresist pattern 91.

At step S5, the conductive material layer 30 and the semiconductor material layer 20 are simultaneously etched for the first time to form the conductive portion 300 and the active layer 2, where the side surface of the conductive portion 300 is continuous with the side surface of the active layer 2.

At step S6, a thinning process on the first photoresist pattern 91 is performed using a photomask to form the second photoresist pattern 92.

At step S7, the conductive portion 300 is etched for the second time to form the conductive layer 3.

In some embodiments, the material of the active layer 2 is an oxide semiconductor material, and the oxide semiconductor material may include any one of indium gallium zinc oxide, indium zinc oxide, tin-doped zinc oxide, aluminum-doped indium oxide, and the like.

FIGS. 6A to 6E illustrate during the first etching, the conductive material layer 30 and the semiconductor material layer 20 are simultaneously etched so that the side surface of the conductive portion 300 formed after etching is continuous with the side surface of the active layer 2, and the conductive portion 300 is avoided from being undercut from the bottom of the active layer 2 by the etching solution during the second etching to the conductive material 30, so that the retraction width of the edge of the conductive layer 3 is reduced from 1.4 to 1.7 microns to 1 to 1.3 microns compared with the edge of a same side of the active layer 2, and the situation of the CD loss may be improved.

Referring to FIG. 6A, the gate 4 and the gate insulating layer 6 may be formed on the substrate 1 before the semiconductor material layer 20 is formed on the substrate 1, and the semiconductor material layer 20 is formed on the surface of the gate insulating layer 6 away from the substrate 1.

Referring to FIG. 6A, the conductive material layer 30 has a double-layer structure, and the conductive material layer 30 includes a first sub-conductive material layer 30a and a second sub-conductive material layer 30b, and the second sub-conductive material layer 30b is formed on a surface of the first sub-conductive material layer 30a away from the substrate 1. A photoresist layer 9 is disposed on the second sub-conductive material layer 30b.

Referring to FIG. 6B, exposure and development processing is performed on the photoresist layer 9 using a photomask to form a first photoresist pattern 91.

As shown in FIG. 6E, the conductive layer 3 formed by etching the conductive material layer 30 may have a double-layer conductive structure. The conductive layer 3 includes a first sub-conductive layer 31 and a second sub-conductive layer 32, and the second sub-conductive layer 32 is disposed on the surface of the first sub-conductive layer 31 away from the substrate 1.

In some embodiments, the material of the first sub-conductive layer 31 includes any one of molybdenum, a molybdenum-titanium alloy, and a molybdenum-niobium alloy, and the material of the second sub-conductive layer 32 includes copper.

In some embodiments, the ratio of the thickness of the first sub-conductive layer 31 to the thickness of the second sub-conductive layer 32 is greater than or equal to 0.015 and less than or equal to 0.072.

In some embodiments, referring to FIG. 1, the thickness of the first sub-conductive layer 31 is greater than or equal to 120 microns and less than or equal to 180 microns, and the thickness of the second sub-conductive layer 32 is greater than or equal to 2500 microns and less than or equal to 8000 microns. For example, the thickness of the first sub-conductive layer 31 may be 120 microns, 140 microns, 160 microns, 180 microns, etc., and the thickness of the second sub-conductive layer 32 may be 2500 microns, 3000 microns, 5000 microns, 7000 microns, or 8000 microns, etc.

In some embodiments, step S5 includes etching the conductive material layer 30 and the semiconductor material layer 20 using a composite etching solution. The composite etching solution may etch the conductive material layer 30 and the semiconductor material layer 20 simultaneously, so that the edge of the conductive portion 300 formed by the first etching is continuous with the edge of a same side of the active layer 2, and the edge of the active layer 2 is avoided from being retracted inward compared with the edge of a same side of the conductive portion 300, so that the conductive portion 300 may be avoided from being undercut from the bottom of the active layer 2 by the etching solution during the second etching, thereby reducing the CD loss may be reduced from 3.5 microns to 1.9 microns, thereby improving the CD loss and improving the process accuracy of the display panel.

In some embodiments, the materials of the composite etching solution include hydrofluoric acid, hydrogen peroxide, sulfuric acid, and nitric acid.

In some embodiments, the materials of the composite etching solution includes hydrofluoric acid having a mass fraction of less than 0.1%, hydrogen peroxide having a mass fraction of more than or equal to 15% and less than or equal to 25%, sulfuric acid having a mass fraction of more than or equal to 2% and less than or equal to 7%, nitric acid having a mass fraction of more than or equal to 2% and less than or equal to 7%, and water having a mass fraction of more than or equal to 60% and less than or equal to 80%.

Referring to FIGS. 6C and 6D, before the conductive portion 300 is etched for the second time, as shown in FIG. 6C, the first photoresist pattern 91 is thinned using a photomask, and specifically, a portion of the first photoresist pattern 91 corresponding to the channel of the transistor may be removed by ashing treatment to form the second photoresist pattern 92, as shown in FIG. 6D. When the second etching is performed, the portion of the conductive portion 300 not covered with the photoresist 9 is etched and is removed to obtain the conductive layer 3 shown in FIG. 6E.

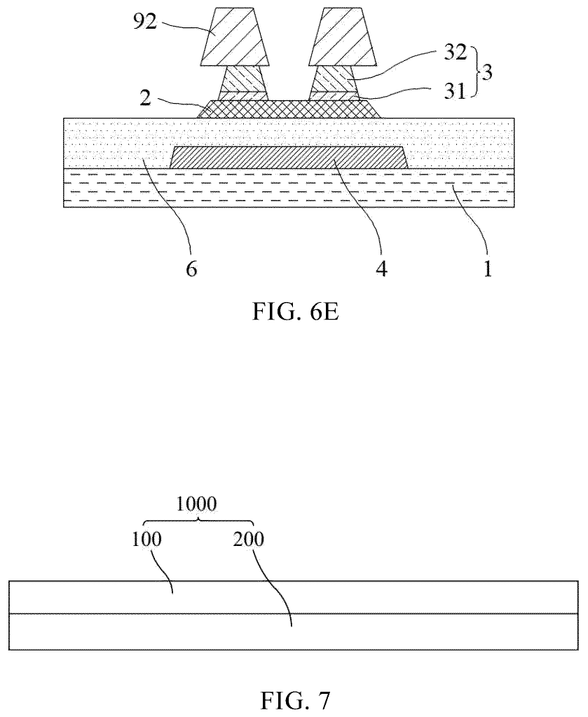

Based on the display panel provided by the above-described embodiments of the present disclosure, the embodiments of the present disclosure further provide a display device. Referring to FIG. 7, FIG. 7 is a schematic view of a display device 1000 provided according to some embodiments of the present disclosure. The display device 1000 includes a display panel 100 and a housing 200, and the display panel 100 is disposed on the housing 200. The display panel 100 may be the display panel provided by any one of the above embodiments. The display device provided by the embodiments of the present disclosure may achieve the same technical effect as the display panel provided by any one of the above embodiments, and will not be repeatedly described here.

The embodiments of the present disclosure provide a display panel, a manufacturing method of the display panel, and a display device, where the display panel includes a substrate, an active layer, and a conductive layer. The active layer is disposed on a side of the substrate, and the conductive layer is disposed on a side of the active layer away from the substrate. By simultaneously patterning the conductive layer and the active layer, the side surface of the patterned conductive layer is continuous with the side surface of the active layer, so that it may be avoided that the etching solution undercuts the conductive layer from the bottom of the active layer during the second patterning process, so that the conductive layer may be retracted inward compared to an edge of a same side of the active layer by a width greater than or equal to 1 micron and less than or equal to 1.3 microns, thereby improving the situation of CD loss.

In the description of the present disclosure, terms such as “first,” “second,” and the like are used solely for descriptive purposes and should not be construed as indicating or implying relative importance or specifying the quantity of technical features being referred to. Therefore, features defined by “first” and “second” may explicitly or implicitly include one or more of these features. In the description of this application, “plurality” means two or more, unless expressly and specifically defined otherwise.

In the foregoing embodiments, the descriptions of each of the embodiments have their own emphases, and for parts not described in detail in a certain embodiment, reference may be made to relevant descriptions of other embodiments.

The embodiments, implementations and related technical features of the present disclosure can be combined and replaced with each other without conflict.

What described above are only preferred embodiments of the present disclosure and are not intended to limit the present disclosure in any form. Any simple modification, equivalent change and embellishment to the above embodiments based on the technical essence of the present disclosure without departing from the content of the technical solution of the present disclosure still fall within the scope of the technical solution of the present disclosure.

What is claimed is:

1. A display panel, comprising:
a substrate;
an active layer disposed on a side of the substrate;
a conductive layer disposed on a side of the active layer away from the substrate;
wherein an edge of the conductive layer is retracted inward compared to an edge of a same side of the active layer by a width greater than or equal to 1 micron and less than or equal to 1.3 microns.

2. The display panel of claim 1, wherein the conductive layer comprises a first sub-conductive layer and a second sub-conductive layer, the second sub-conductive layer being disposed on a surface of the first sub-conductive layer away from the active layer;
wherein a ratio of a thickness of the first sub-conductive layer to a thickness of the second sub-conductive layer is greater than or equal to 0.015 and less than or equal to 0.072.

3. The display panel of claim 2, wherein a side surface of the first sub-conductive layer is disposed continuously with a side surface of the second sub-conductive layer.

4. The display panel of claim 2, wherein an included angle between a side surface of the first sub-conductive layer and a bottom surface of the first sub-conductive layer is a first included angle, and an included angle between a side surface of the second sub-conductive layer and a bottom surface of the second sub-conductive layer is a second included angle, and the first included angle is equal to the second included angle.

5. The display panel of claim 4, wherein the first included angle is greater than or equal to 40 degrees and less than or equal to 70 degrees.

6. The display panel of claim 4, wherein an included angle between a side surface of the active layer and a bottom surface of the active layer is a third included angle, and the third included angle is smaller than the first included angle.

7. The display panel of claim 6, wherein the third included angle is greater than or equal to 30 degrees and less than or equal to 50 degrees.

8. The display panel of claim 1, wherein an orthographic projection of the conductive layer on the active layer is located within the active layer.

9. The display panel of claim 1, wherein the conductive layer comprises a source and a drain, and the active layer comprises a first active portion, the source and the drain being spaced apart on a surface of the first active portion away from the substrate;
wherein a distance between the source and the drain is greater than or equal to 3 microns and less than or equal to 3.5 microns along a channel length direction of the first active portion.

10. The display panel of claim 1, wherein the display panel comprises a display area and a border area disposed at a periphery of the display area, and the conductive layer comprises a plurality of fan-out traces disposed in the border area;
wherein the active layer comprises a plurality of second active portions, and orthographic projections of the fan-out traces on the active layer are located in the second active portions.

11. The display panel of claim 10, wherein a distance between centers of two adjacent ones of the fan-out traces is greater than or equal to 7 microns and less than or equal to 8 microns along a line width direction of the fan-out traces.

12. The display panel of claim 2, wherein the thickness of the first sub-conductive layer is greater than or equal to 120 microns and less than or equal to 180 microns, and the thickness of the second sub-conductive layer is greater than or equal to 2500 microns and less than or equal to 8000 microns.

13. The display panel of claim 2, wherein an etch selectivity ratio of a material of the first sub-conductive layer is less than an etch selectivity ratio of a material of the second sub-conductive layer.

14. The display panel of claim 2, wherein a material of the first sub-conductive layer comprises any one of molybdenum, a molybdenum-titanium alloy, and a molybdenum-niobium alloy, and a material of the second sub-conductive layer comprises copper.

15. The display panel of claim 1, wherein the display panel further comprises a gate disposed between the active layer and the substrate.

16. The display panel of claim 1, wherein a material of the active layer comprises an oxide semiconductor material.

17. A method for manufacturing a display panel, comprising:
forming a semiconductor material layer on a side of a substrate;
forming a conductive material layer on a side of the semiconductor material layer away from the substrate;
forming a photoresist layer on the conductive material layer;
exposing and developing the photoresist layer using a photomask to form a first photoresist pattern;
simultaneously performing a first etching on the conductive material layer and the semiconductor material layer using the first photoresist pattern to form a conductive portion and an active layer, wherein a side surface of the conductive portion is continuous with a side surface of the active layer;
thinning the first photoresist pattern using the photomask to form a second photoresist pattern; and
performing a second etching on the conductive portion using the second photoresist pattern to form a conductive layer;
wherein an edge of the conductive layer is retracted inward compared to an edge of a same side of the active layer by a width greater than or equal to 1 micron and less than or equal to 1.3 microns.

18. The method for manufacturing the display panel of claim 17, wherein the conductive layer comprises a first sub-conductive layer and a second sub-conductive layer, the second sub-conductive layer being disposed on a surface of the first sub-conductive layer away from the active layer;
wherein a ratio of a thickness of the first sub-conductive layer to a thickness of the second sub-conductive layer is greater than or equal to 0.015 and less than or equal to 0.072.

19. The method of manufacturing the display panel of claim 17, wherein the step of simultaneously performing a first etching on the conductive material layer and the semiconductor material layer using the first photoresist pattern comprises:
etching the conductive material layer and the semiconductor material layer using a composite etching solution;
wherein materials of the composite etching solution comprise hydrofluoric acid, hydrogen peroxide, sulfuric acid, and nitric acid.

20. A display device, comprising a display panel, wherein the display panel comprises:
a substrate;
an active layer disposed on a side of the substrate;
a conductive layer disposed on a side of the active layer away from the substrate;
wherein an edge of the conductive layer is retracted inward compared to an edge of a same side of the active layer by a width greater than or equal to 1 micron and less than or equal to 1.3 microns.
